(19) United States
(12) Patent Application Publication
(10) Pub. No.: US 2002/0098673 A1
(43) Pub. Date: Jul. 25, 2002

(54) Method for fabricating metal interconnects

(76) Inventors: Ming-Shi Yeh, Changhua Hsien (TW); Wen-Yi Hsieh, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/886,774

(22) Filed: Jan. 19, 2001

(51) Int. Cl. H01L 21/4763; H01L 21/44

(52) U.S. Cl. 438/618; 438/638

(57) ABSTRACT

A method for forming metal interconnects. A substrate having a metal line is provided. A dielectric layer with an opening exposing the metal line is formed over the substrate, which dielectric layer further comprises an etching stop layer. After forming a covering layer conformal to a profile of the opening over the substrate, a portion of the covering layer in a bottom of the opening is removed to expose the metal line. A conformal barrier layer and a metal layer are formed sequentially in the opening and the metal layer fills up the opening. After forming a cap layer covering the substrate, the cap layer and the dielectric layer are defined to form a second opening. Next, remove the dielectric layer exposed by the opening, thus forming air-gaps.

### CROSS-REFERENCE TO RELATED APPLICATION

This application claims the priority benefit of Taiwan application serial no. 90113651, filed on Jun. 6, 2001.

### BACKGROUND OF THE INVENTION

1. Field of the Invention

The present invention relates to a method for fabricating semiconductor devices. More particularly, the present invention relates to a method of fabricating metal interconnects.

2. Description of the Related Art

Metal lines (wires) are commonly used for electrically connecting various devices in the semiconductor manufacture processes. The metal lines are connected to the semiconductor devices through contacts, while the metal lines are connected through interconnects. As the ICs enter into the sub-micron processes, copper metal, instead of conventional aluminum, is used for interconnects. Compared with aluminum metal, copper has an electromigration resistance 30 to 100 times higher, a via resistance 10 to 20 times lower and a resistance 30% lower. Therefore, the copper wires in combination with low k materials as inter-metal dielectrics can effectively reduce RC delay and electromigration. Because the etching step of copper metal is difficult to control, a damascene process is usually used to fabricate copper lines.

The low k dielectric materials for the prior art metal damascene structure are required to has a dielectric constant lower than 3.0, for example, vapor-phase deposition polymers (VPDP), spin-on dielectric (SOD) or spin-on glass (SOG). If spin-on dielectric, such as, polyarylene ether, SILK, is used for the inter-metal dielectric, the strength and hardness of spin-on dielectric is lower than that of copper metal and of the barrier layer, resulting in weak points in the copper metal or the barrier layer. It is because the majority of stress during the mechanical process is taken by the copper metal and the barrier layer, rather than the softer inter-metal dielectric layer, thus causing weak points and defects in the copper metal and the barrier layer. This can greatly reduce yields.

On the other hand, air-gaps can be used to decrease the dielectric constant of the spin-on dielectric from a value of 2-3 to a value of about 1.0, thereby reducing RC delay and electromigration.

### SUMMARY OF THE INVENTION

According to above, the invention provides a method for fabricating metal interconnects, which can prevent the copper metal and the barrier layer from forming weak points and defects by stress.

The present invention provides a method for fabricating metal interconnects by forming air-gaps in the dielectric layer of the damascene structure, so that the dielectric constant can be decreased and the RC delay and electromigration can be reduced.

As embodied and described broadly herein, the invention provides a method for forming a metal interconnect, comprising: providing a substrate having a metal line; forming sequentially a first dielectric layer, a first etching stop layer, a second dielectric layer and a second etching stop layer on the substrate; defining the first dielectric layer, the first etching stop layer, the second dielectric layer and the second etching stop layer to form a first opening; forming a covering layer on the second etching stop layer, conformal to a profile of the first opening; removing a portion of the covering layer in a bottom of the opening, to expose the metal line; forming sequentially a conformal barrier layer and a metal layer in the first opening; forming a cap layer covering the substrate; defining the cap layer, the first dielectric layer, the first etching stop layer, the second dielectric layer and the second etching stop layer to form a second opening; and removing the first dielectric layer and the second dielectric layer exposed by the second opening, thus forming air-gaps.

Therefore, the present invention can prevent the barrier layer and the metal layer from forming weak points by covering (wrapping) the metal layer of the metal damascene structure with a silicon nitride layer, thus increasing yield. Because air-gaps are formed, the dielectric constant is decreased and RC delay and electromigration are reduced, thereby enhancing device performance.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A through FIG. 1H are schematic, cross-sectional views showing process steps for forming a metal interconnect according to one preferred embodiment of the invention; and

FIG. 2A through FIG. 2B are schematic, cross-sectional views showing process steps for forming a metal interconnect according to one preferred embodiment of the invention.

### DESCRIPTION OF THE PREFERRED EMBODIMENTS

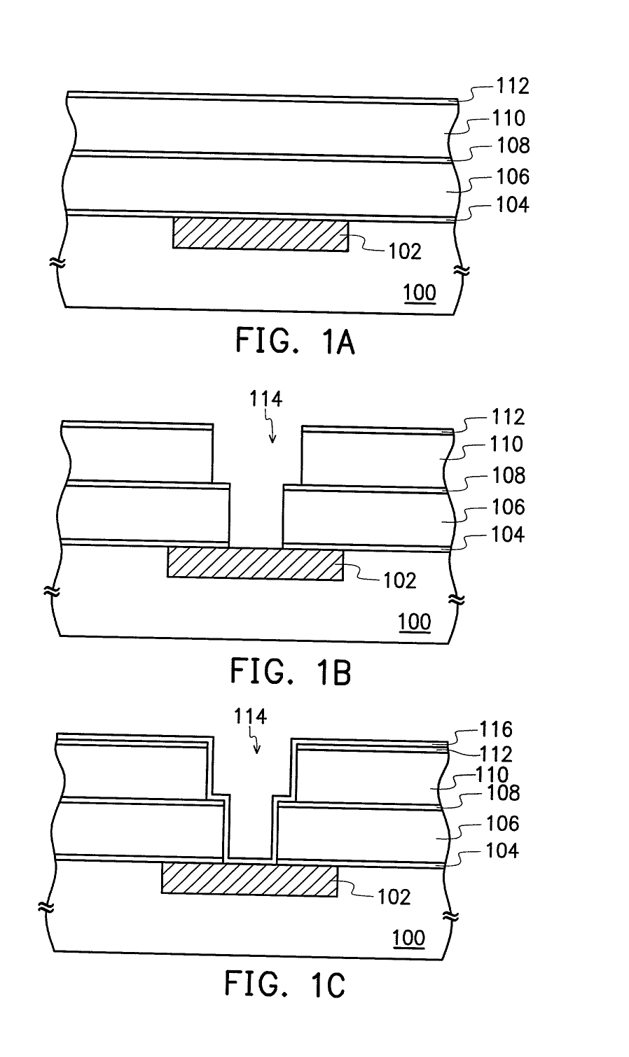

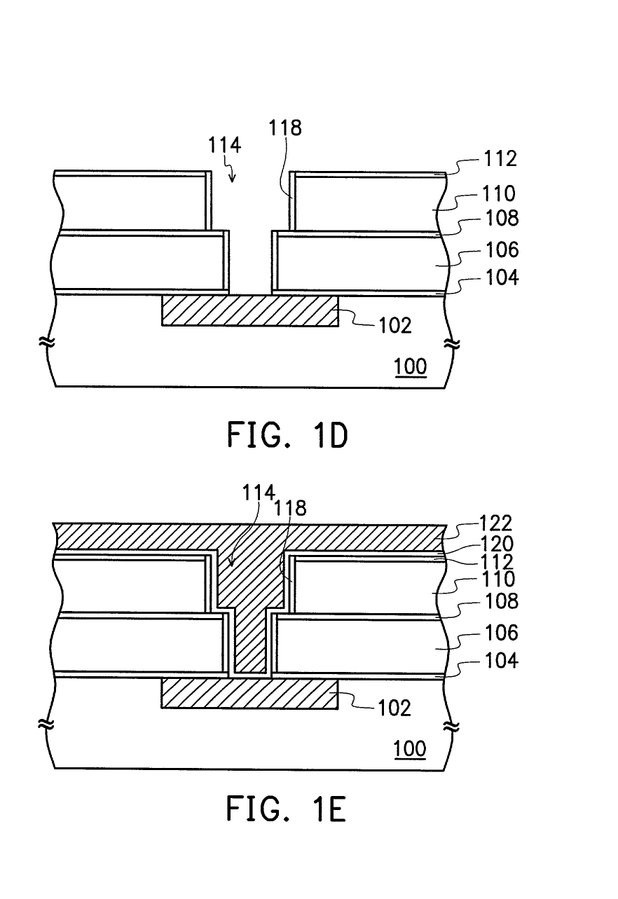

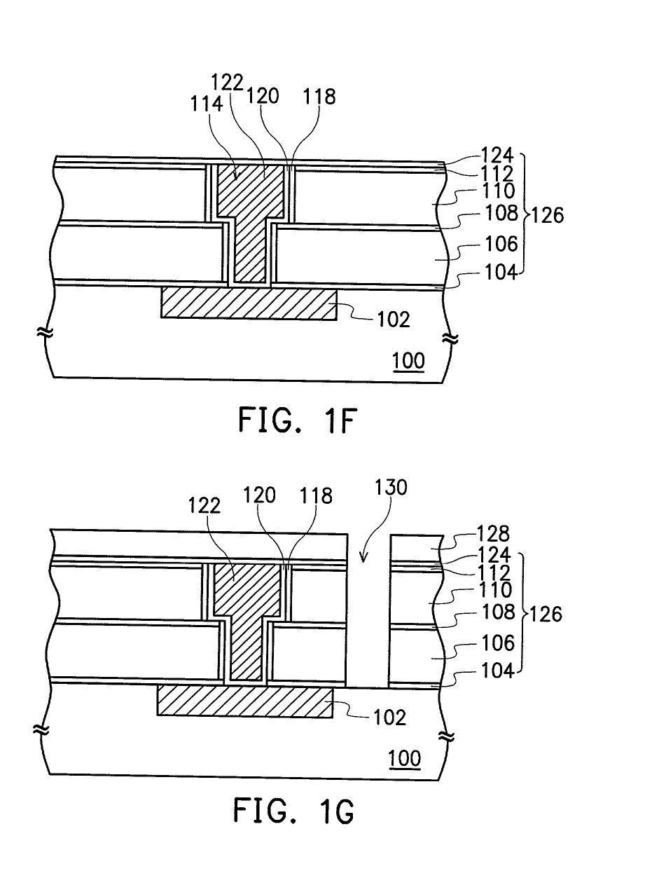

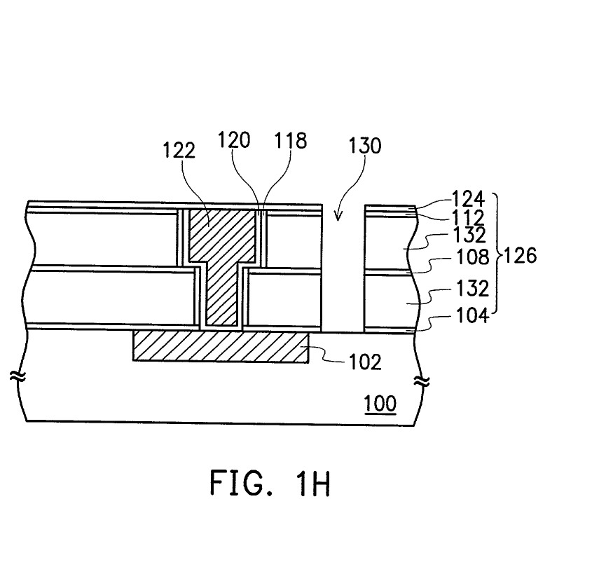

FIG. 1A through FIG. 1H are schematic, cross-sectional views showing process steps for forming a metal interconnect according to one preferred embodiment of the invention.

As shown in FIG. 1A, a substrate 100 having a metal line 102 is provided. The substrate 100 is shown in a simplified display without showing other components within. A first cap layer 104 is formed on the top of the metal line 102. A first dielectric layer 106, a first etching stop layer 108, a second dielectric layer 110 and a second etching stop layer 112 are formed sequentially over the substrate 100 and the metal line 102. The first and second dielectric layer 106, 110 are preferably formed of low-k dielectric materials, for example, poly arylene ether (SILK), fluorinated poly arylene ether (FLARE), hydrogen silsesquioxane (HSQ) or fluorinated hydrocarbon, formed by spinning on. The first cap layer 104, the first and second etching stop layers 108, 112 are preferably formed of, for example, silicon nitride by chemical vapor deposition (CVD).

Referring to FIG. 1B, an opening 114 is formed. The opening 114 can be a dual damascene opening, an opening for a metal line, a via opening for a plug, a contact opening for a plug or an opening for a damascene structure. The opening 114 can be a trench-first, a via-first or a self-aligned opening. Taking the via-first opening as an example, a first photoresist layer (not shown) is formed on the etching stop layer 112 and patterned. An etching step is carried out to partially remove the first and second dielectric layer 106, 110, with the patterned first photoresist layer serving as a mask, until the metal line 102 is exposed whereby a via opening is formed. After removing the first photoresist layer, a patterned second photoresist layer (not shown) is formed over the second etching stop layer 112. Using the patterned second photoresist layer as a mask, a trench pattern is thereafter formed to expose the first etching stop layer 108, thereby completing formation of the opening 114.

Referring to FIG. 1C, a covering layer 116 is formed over the substrate 100, conformal to the profile of the opening 114 and covering the second etching stop layer 112. The covering layer 116 has an etching selectivity different from that of the first and second dielectric layers 106, 110. Furthermore, the covering layer 116 has a higher strength and hardness than a metal layer and a barrier layer formed in the following steps. For example, the covering layer 116 is made of silicon nitride by CVD.

Referring to FIG. 1D, a portion of the covering layer 116 is removed to form spacers 118 on sidewalls of the first and second dielectric layers 106, 110 and expose the surface of the metal line 102 in the substrate 100. The spacers 118 are formed by, for example, dry etching or anisotropic etching.

Referring to FIG. 1E, a barrier layer 120 is formed over the substrate, conformal to the profile of the opening 114 and covering the second etching stop layer 112. The barrier layer 120 is made of, for example, tantalum nitride (TaN), titanium nitride (TiN) or titanium silicide/nitride materials. The barrier layer 120 can be formed, for example, by DC sputtering. Normally, a titanium layer is formed by DC magnetron sputtering and the titanium layer is then displaced in an environment containing nitrogen or ammonia. By rapid thermal process (RTP), the titanium layer is transformed into a titanium nitride layer. Or a reactive sputtering is used to deposit titanium nitride. A mixture of argon and nitrogen is used as a reactive gas. Through ion bombardment, the titanium sputtered from a titanium target is reacted with the nitrogen ion to form a titanium nitride layer. Next, a metal layer 122 is formed on the barrier layer 120 and fills up the opening 114. The metal layer 122 can be formed of, for example, copper metal. The metal layer 122 includes, for example, a copper seed layer formed by physical vapor deposition (PVD), CVD or sputtering and an electroplating copper layer.

Referring to FIG. 1F, a first CMP process is performed to planarize the metal layer 122, using the barrier layer 120 as a polishing stop layer. Next, a second CMP process with a slurry for both the barrier layer 120 and the metal layer 122 is performed to remove the barrier layer 120 and planarize the metal layer 122, until the second etching stop layer 112 is exposed. A second cap layer 124 is formed over the substrate 100, covering the metal layer 122 and the second etching stop layer 112. The second cap layer 142 is made of, for example, silicon nitride by CVD. For example, the second cap layer 124, the spacers 118 and the first etching stop layer 108 are made of silicon nitride, together with copper metal layer 122, thus forming a nitride-covering copper dual damascene structure 126.

Referring to FIG. 1G, a patterned third photoresist layer 128 is formed on the second cap layer 124. Using the patterned third photoresist layer 128 as a mask, an opening 130 is formed in the first and second dielectric layers 106, 110 until the substrate 100 is exposed. Afterwards, the patterned third photoresist layer 128 is removed.

Referring to FIG. 1H, remove the exposed first and second dielectric layers 106 110 from the opening 130 to form air-gaps 132, thus completing air-gap containing low dielectric constant structure. For example, ozone or oxygen plasma can be used to remove the first and second dielectric layers 106, 110 that are exposed by the opening 130. Because the material of the first and second dielectric layers 106, 110 has a different etching selectivity from the material of the second cap layer 124, the spacers 118 and the first etching stop layer 108, the first and second dielectric layers 106, 110 can be selectively removed, completing the nitride-covering copper dual damascene structure with air-gaps.

The method cited above can be applied to fabricate multi-level metal interconnects, by repeating the processes illustrated in FIG. 1A to FIG. 1F for forming a plurality of the nitride-covering copper dual damascene structures.

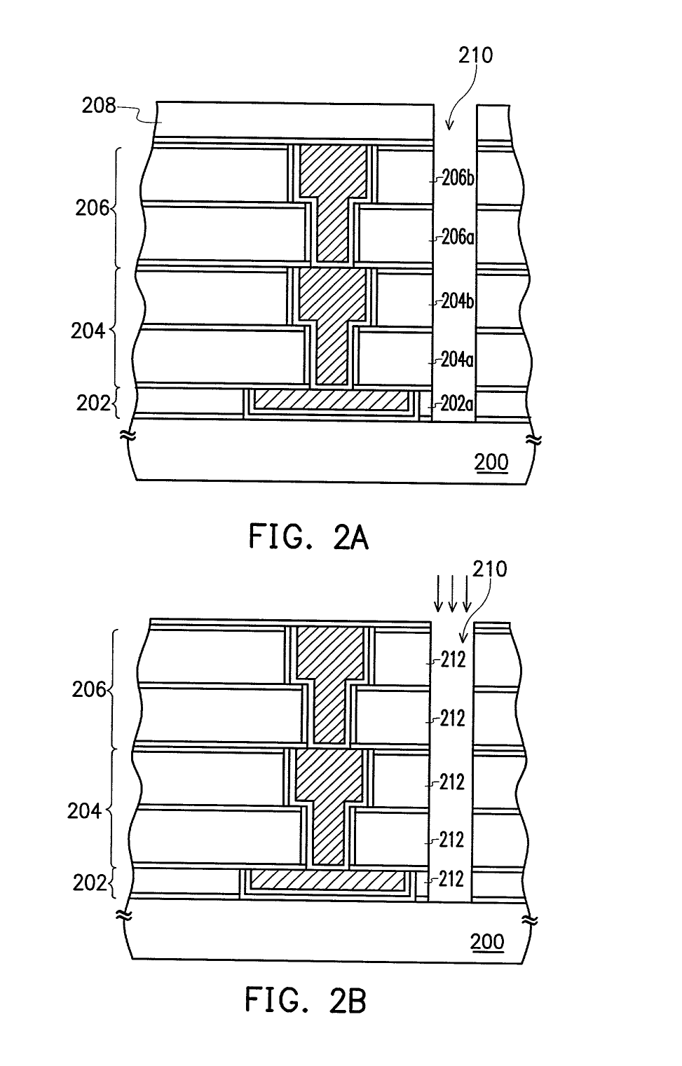

Referring to FIG. 2A, a substrate 200 (the components within the substrate not shown) is provided with a nitride-covering damascene structure 202, a first nitride-covering copper dual damascene structure 204 and a second nitride-covering copper dual damascene structure 206. The nitride-covering damascene structure 202, the first nitride-covering copper dual damascene structure 204 and the second nitride-covering copper dual damascene structure 206 are electrically coupled to one another. A photoresist layer 208 is formed covering the whole substrate 200. The photoresist layer 208 is patterned. Using the patterned photoresist layer 208 as a mask, an opening 210 is formed by photolithography and etching, exposing the substrate 200. Afterwards, the patterned photoresist layer 208 is removed.

Referring to FIG. 2B, remove exposed dielectric layers 202a, 204a, 204b, 206a and 206b by etching using either ozone or oxygen plasma, so that air-gaps 212 are formed in the positions of the dielectric layers 202a, 204a, 204b, 206a and 206b. As a result, a nitride-covering multi-level metal interconnects with air-gaps are completed.

Therefore, the method can prevent the barrier layer and the metal layer from forming weak points by covering (wrapping) the metal layer of the metal damascene structure with a silicon nitride layer, thus increasing yield. Because air-gaps are formed, the dielectric constant decreases to about 1.0. As a result, RC delay and electromigration are reduced, thereby enhancing device performance.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a metal interconnect, comprising:
providing a substrate having a metal line;
forming a first dielectric layer on the substrate;
forming a first etching stop layer on the first dielectric layer;
forming a second dielectric layer on the first etching stop layer;
forming a second etching stop layer on the second dielectric layer;
defining the first dielectric layer, the first etching stop layer, the second dielectric layer and the second etching stop layer to form a first opening, wherein the first opening exposes the metal line in the substrate;
forming a covering layer on the second etching stop layer, conformal to a profile of the first opening;
removing a portion of the covering layer in a bottom of the opening, to expose the metal line;
forming sequentially a conformal barrier layer and a metal layer in the first opening, wherein the metal layer fills up the first opening, and wherein the covering layer has a hardness higher that the metal layer and the barrier layer;
forming a cap layer covering the substrate;
defining the cap layer, the first dielectric layer, the first etching stop layer, the second dielectric layer and the second etching stop layer to form a second opening, wherein the second opening exposes a portion of the substrate; and
removing the first dielectric layer and the second dielectric layer exposed by the second opening, thus forming air-gaps.

2. The method of claim 1, wherein the first opening can be one selected from the following group consisting of a dual damascene opening, an opening for a metal line, a via opening for a plug, a contact opening for a plug and an opening for a damascene structure.

3. The method of claim 1, wherein the covering layer has a different etching selectivity from the first and second dielectric layers.

4. The method of claim 1, wherein a material for forming the covering layer, the first and second etching stop layers comprises silicon nitride.

5. The method of claim 1, wherein the step of removing a portion of the covering layer in the bottom of the first opening includes anisotropic etching.

6. The method of claim 5, wherein the step of removing a portion of the covering layer in the bottom of the first opening includes dry etching.

7. The method of claim 1, wherein a material for forming the metal layer comprises copper.

8. The method of claim 1, wherein a material of the first and second dielectric layers is selected from the following group consisting of poly arylene ether (SILK), fluorinated poly arylene ether (FLARE), hydrogen silsesquioxane (HSQ) and fluorinated hydrocarbon.

9. The method of claim 1, wherein a method for forming the first and second dielectric layers comprises spinning on.

10. The method of claim 1, wherein the step of removing the first and second dielectric layers includes using either ozone or oxygen plasma.

11. A method for forming a metal interconnect, comprising:
(a) providing a substrate having a first metal line structure;
(b) forming sequentially a first dielectric layer, a first etching stop layer, a second dielectric layer and a second etching stop layer over the substrate;
(c) defining the first dielectric layer, the first etching stop layer, the second dielectric layer and the second etching stop layer to form a first opening, wherein the first opening exposes the first metal line structure in the substrate;
(d) forming a covering layer on the second etching stop layer, conformal to a profile of the first opening;
(e) removing a portion of the covering layer in a bottom of the opening, to expose the first metal line structure;
(f) forming sequentially a conformal barrier layer and a metal layer in the first opening, wherein the metal layer fills up the first opening, and wherein the covering layer has a hardness higher that the metal layer and the barrier layer;
(g) forming a cap layer covering the substrate, thus completing a second metal line structure;
(h) repeating the above steps (b) to (g), to form a plurality of third metal line structures, wherein the first, second and third metal line structures are electrically coupled;
(i) defining the cap layers, the first dielectric layers, the first etching stop layers, the second dielectric layers and the second etching stop layers to form a second opening, wherein the second opening exposes a portion of the substrate; and
(j) removing the first dielectric layers and the second dielectric layers exposed by the second opening, thus forming air-gaps.

12. The method of claim 11, wherein the first opening can be one selected from the following group consisting of a dual damascene opening, an opening for a metal line, a via opening for a plug, a contact opening for a plug and an opening for a damascene structure.

13. The method of claim 11, wherein the covering layer has a different etching selectivity from the first and second dielectric layers.

14. The method of claim 11, wherein a material for forming the covering layer, the first and second etching stop layers comprises silicon nitride.

15. The method of claim 11, wherein the step of removing a portion of the covering layer in the bottom of the first opening includes anisotropic etching.

16. The method of claim 15, wherein the step of removing a portion of the covering layer in the bottom of the first opening includes dry etching.

17. The method of claim 11, wherein a material for forming the metal layer comprises copper.

18. The method of claim 11, wherein a material of the first and second dielectric layers is selected from the following group consisting of poly arylene ether (SILK), fluorinated poly arylene ether (FLARE), hydrogen silsesquioxane (HSQ) and fluorinated hydrocarbon.

19. The method of claim 11, wherein a method for forming the first and second dielectric layers comprises spinning on.

20. The method of claim 11, wherein the step of removing the first and second dielectric layers includes using either ozone or oxygen plasma.
